(19) United States
(12) Patent Application Publication
(10) Pub. No.: US 2024/0029755 A1
(43) Pub. Date: Jan. 25, 2024

(54) INTELLIGENT SPEECH OR DIALOGUE ENHANCEMENT

(71) Applicant: BOSE CORPORATION, Framingham, MA (US)

(72) Inventors: Elio Dante QUERZE, III, Arlington, MA (US); Shuo ZHANG, Cambridge, MA (US); Isaac Keir JULIEN, Cambridge, MA (US); Yang LIU, Boston, MA (US); Miriam ISRAELOWITZ, Natick, MA (US); Stoyan I. ILIEV, Framingham, MA (US); Edward MANIET, Auburn, MA (US); Santiago CARVAJAL, Ashland, MA (US); Michael W. STARK, Acton, MA (US); James Michael MCHUGH, Jamaica Plain, MA (US)

(21) Appl. No.: 17/813,542

(22) Filed: Jul. 19, 2022

(51) Int. Cl. G10L 21/0316; G10L 25/78

(52) U.S. Cl. CPC G10L 21/0316; G10L 25/78

(57) ABSTRACT

Processes, methods, systems, and devices are disclosed for intelligently detecting speech or in audio signals and smoothly transitioning to mode that enables a user to better understand the speech. For example, aspects of the present disclosure provide method for processing and producing audio signals. During playback of an audio signal, the method analyzes content of the audio signal prior to the playback of the content to determine whether one or more predefined conditions are met to indicate that the content includes speech. In response to determining the one or more predefined conditions are met, the method automatically applies to the audio signal a first playback equalization configured to enhance the speech within the content. In response to determining the one or more predefined conditions are not met, the method comprises applying to the audio signal no playback equalization or a second playback equalization different from the first playback equalization.

### FIELD

Aspects of the disclosure generally relate to audio signal processing.

### BACKGROUND

In sound recording and reproduction, an equalizer may perform equalization to adjust magnitudes of different frequency bands in an audio signal. For example, the equalizer may use filters to adjust bass and treble to enhance listening experience. The equalization may be dynamically adjusted by a user in real time, or include one or more preset profiles for different genres of audio input (e.g., jazz, classical, pop, etc.).

In home theaters, different surround sound configurations and/or different recording or compression profiles may cause speech or dialogue to be less intelligible than intended. A user may prefer enhancing sound components (e.g., by increasing magnitudes of relevant frequency bands) of the speeches or dialogues using an equalization profile.

### SUMMARY

All examples and features mentioned herein can be combined in any technically possible manner.

Aspects of the present disclosure provide a method for processing and producing audio signals. The method includes detecting, in an original set of audio signals, a speech component using a trained machine-learning network based on mixed categories of audio content, the speech component consisting of sound elements carrying linguistic meanings. The method includes enhancing the detected speech component by transitioning from an original equalization mode to a speech equalization mode that enables a user to better understand the linguistic meanings therein. The method further includes outputting the original set of audio signals in the original equalization mode absent the detection of the speech component.

In aspects, detecting the speech component using the trained machine-leaning network is based on calculating a root mean square of respective energy levels of each category of the mixed categories of audio content. In some cases, the trained machine-learning network includes a deep learning model that estimates the respective energy levels of each category of the mixed categories of audio content, the mixed categories of audio content including the speech component, a music component, and a singing component. In some cases, detecting the speech component includes determining a ratio of an energy level of the speech component and an overall energy level exceeding a threshold value.

In some cases, the speech component includes sounds in which meanings are conveyed based on linguistic characteristics. The music component includes sounds that lack linguistic characteristics. The singing component includes a mixture of sounds that simultaneously includes a component of linguistic expressions and a component of musical expressions. In some cases, the trained machine-learning network may be trained to identify the respective category of the mixed categories of audio content and the threshold value based on a known database of cinematic content.

In some cases, detecting the speech component includes processing ongoing audio signals at an advanced time before the transitioning or outputting operations.

In aspects, enhancing the speech component includes fading from the original equalization mode into the speech equalization mode gradually. For example, the speech equalization mode includes at least one of: increasing a magnitude or a contrast of speech related frequency bands to improve intelligibility of the speech component; decreasing a magnitude of non-speech related frequency bands or signal channels; or altering an equalization setting or a dynamic range compression setting on the non-speech related frequency bands or signal channels.

In aspects, enhancing the detected speech component is performed in a first device and outputting the original set of audio signals is performed in a second device. For example, the first device and the second device are paired in a short-range wireless communication network. In some cases, the method further includes extracting the detected speech component and playing the extracted speech component in a third device. In some cases, the first device, the second device, and the third device are configured to produce a mixed surround sound.

In aspects, outputting the original set of audio signals includes determining a disappearance of the speech component.

Aspects of the present disclosure provide an apparatus for processing and producing audio signals. The apparatus includes a memory; and a processor coupled with the memory. The processor and the memory are configured to detect, in an original set of audio signals, a speech component using a trained machine-learning network based on mixed categories of audio content, the speech component consisting of sound elements carrying linguistic meanings. The processor and the memory are configured to enhance the detected speech component by transitioning from an original equalization mode to a speech equalization mode that enables a user to better understand the linguistic meanings therein. The processor and the memory are further configured to output the original set of audio signals in the original equalization mode absent the detection of the speech component.

In aspects, the processor and memory are configured to enhance the detected speech component and output the original set of audio signals in a second apparatus. In some cases, the apparatus includes a sound bar configured to output a surround sound and the second apparatus includes a noise-canceling headphone. In some cases, the apparatus includes a noise-canceling headphone; and the second apparatus includes a sound bar configured to output a surround sound.

In aspects, the processor and the memory are configured to enhance the speech component by fading from the original equalization mode into the speech equalization mode gradually.

In aspects, the processor and the memory are configured to extract the detected speech component and play the extracted speech component in a third device. In some cases, the first device, the second device, and the third device are configured to produce a mixed surround sound.

Aspects provide a method for audio signal processing, the method comprising: during playback of an audio signal, analyzing content of the audio signal prior to the playback of the content to determine whether one or more predefined conditions are met to indicate that the content includes speech; in response to determining the one or more predefined conditions are met, automatically applying to the audio signal a first playback equalization configured to enhance the speech within the content; an in response to determining the one or more predefined conditions are not met, applying to the audio signal i) no playback equalization or ii) a second playback equalization different from the first playback equalization.

In aspects, the analyzing is performed using a trained machine-learning model. In aspects, the trained machine-learning model comprises a deep learning model that estimates energy levels of the audio signal. In aspects, the energy levels of the audio signals include energy levels of any combination the speech, a music component of the audio signal, and a singing component of the audio signal.

In aspects, the analyzing comprises analyzing metadata associated with the content and wherein the metadata indicates that the content includes speech. In aspects, the analyzing comprises analyzing a voice track of the audio signal, wherein the one or more predefined conditions includes the voice track exceeding a threshold value.

In aspects, the audio signal comprises different channels and the analyzing comprises analyzing the different channels. In aspects, analyzing the different channels comprises comparing correlated content between two channels of the different channels.

In aspects, the analyzing comprises analyzing the center channel of the audio signal.

In aspects, automatically applying to the audio signal the first playback equalization configured to enhance the speech within the content comprises transitioning to the first playback equalization from either i) no playback equalization or ii) the second playback equalization.

In aspects, automatically applying to the audio signal the first playback equalization configured to enhance the speech within the content comprises increasing a volume of the speech within the content relative to other content within the audio signal.

In aspects, automatically applying to the audio signal the first playback equalization configured to enhance the speech within the content comprises decreasing a volume of non-speech content within the audio signal. In aspects, automatically the first playback equalization further comprises applying comprises increasing a volume of the speech within the content.

In aspects, the second playback equalization comprises at least one of low frequency enhancement or music playback enhancement.

In aspects, the at least one of the first playback equalization or the one or more predefined conditions are configurable by a user.

In aspects, the method further comprises analyzing sound in an environment in which the audio signal is to be played back to help determine whether to apply the first playback equalization to the audio signal.

Aspects provide an apparatus for audio signal processing, comprising: a memory; and a processor coupled with the memory, the processor and the memory configured to: during playback of an audio signal, analyze content of the audio signal prior to the playback of the content to determine whether one or more predefined conditions are met to indicate that the content includes speech, in response to determining the one or more predefined conditions are met, automatically apply to the audio signal a first playback equalization configured to enhance the speech within the content, and in response to determining the one or more predefined conditions are not met, apply to the audio signal i) no playback equalization or ii) a second playback equalization different from the first playback equalization.

In aspects, the processor and the memory are configured to detect using a trained machine-learning model. In aspects, the audio signal comprises different channels and the memory and the processor are configured to detect by analyzing the different channels, and wherein analyzing the different channels comprises comparing correlated content between two channels of the different channels.

In aspects, the processor and the memory are configured to detect by analyzing the center channel of the audio signal.

In aspects, the processor and the memory are configured to automatically apply to the audio signal the first playback equalization configured to enhance the speech within the content by transitioning to the first playback equalization from either i) no playback equalization or ii) the second playback equalization.

In aspects, the second playback equalization comprises at least one of low frequency enhancement or music playback enhancement. In aspects, at least one of the first playback equalization or the one or more predefined conditions are configurable by a user.

In aspects, the processor and the memory are further configured to analyze sound in an environment in which the audio signal is to be played back to help determine whether to apply the first playback equalization to the audio signal.

Aspects provide a non-transitory computer readable medium storing instructions that when executed by a device for processing and producing audio signals cause the device to: during playback of an audio signal, analyze content of the audio signal prior to the playback of the content to determine whether one or more predefined conditions are met to indicate that the content includes speech, in response to determining the one or more predefined conditions are met, automatically apply to the audio signal a first playback equalization configured to enhance the speech within the content, and in response to determining the one or more predefined conditions are not met, apply to the audio signal i) no playback equalization or ii) a second playback equalization different from the first playback equalization.

Two or more features described in this disclosure, including those described in this summary section, may be combined to form implementations not specifically described herein.

The details of one or more implementations are set forth in the accompanying drawings and the description below. Other features, objects, and advantages will be apparent from the description and drawings, and from the claims.

### BRIEF DESCRIPTION OF THE DRAWINGS

FIG. 1 illustrates an example system in which aspects of the present disclosure may be implemented.

FIG. 2 illustrates an block diagram of a machine learning network and related components, in accordance with certain aspects of the present disclosure.

FIG. 3A illustrates an example determination of different sound categories in audio signals, in accordance with certain aspects of the present disclosure.

FIG. 3B illustrates an example determination of different sound categories in audio signals, in accordance with certain aspects of the present disclosure.

FIG. 4 illustrates an example equalization processing for speech, in accordance with certain aspects of the present disclosure.

FIG. 5 illustrates an example process for generating training data set, in accordance with certain aspects of the present disclosure.

FIG. 6 is a flow diagram illustrating example operations for automatic speech enhancement, in accordance with certain aspects of the present disclosure.

FIG. 7 is a flow diagram illustrating example operations for automatic speech enhancement, in accordance with certain aspects of the present disclosure.

Like numerals indicate like elements and “speech” and “dialogue” may be used interchangeably.

### DETAILED DESCRIPTION

Because a user often reacts with a substantial delay to audio content, such as in a movie that includes various types of audio signals (e.g., dialogues, music, singing, etc.), the user may make a manual equalization adjustment too late. In addition, manual selection of speech-based equalization profile(s) can be troublesome and discouraging. Accordingly, methods for an automatic (without additional user input) update of equalization profiles in view of speech content, as well as apparatuses and systems configured to implement these methods, are desired.

The present disclosure provides processes, methods, systems, and devices for intelligently detecting speech or dialogue content in audio signals (e.g., by implementing machine learning and artificial intelligence) and smoothly transitioning to a speech equalization mode that enables a user to better understand the linguistic meanings of the speech content in the audio signals. For example, aspects of the present disclosure provide methods for processing and producing audio signals. In an example, the method detects a speech component in an original set of audio signals using a trained machine-learning network based on mixed categories of audio content. Regardless of how the speech component is detected, the detected speech component may be enhanced by transitioning from an original equalization mode to a speech equalization mode that enables a user to better understand the linguistic meanings therein.

Multi-media played at home theaters or entertainment centers often includes different types of movies or television shows. These different types of multi-media may include sound playbacks that benefit from different equalization settings. As an example, a documentary may include substantial verbal narrations. The verbal narrations may benefit from an equalization setting for speech, for example, more than a concert including substantial singing or music. Conventionally, equalization settings may be adjusted on high-fidelity (hi-fi) equipment by applying filters or amplifications over different frequency bands from bass to treble. The hi-fi equipment may allow for manual adjustment or recall of pre-configured equalization settings (e.g., pre-configured for jazz, classical, pop, concert, etc.). However, such manual adjustments or recalls may be inconvenient especially when a user cycles through television channels or when a movie includes different scenes that include different primary sound elements (e.g., dialogue, music, sound effect, etc.).

For example, a user may manually select a pre-configured equalization profile that enhances speech and then realize the media includes music background. The sound quality for the music may be negatively impacted by the selected equalization profile. Likewise, if the user selects a pre-configured equalization profile that enhances music or other sound effects, or in situations with complicated and loud surround sounds, the sound quality for dialogue may be negatively impacted or less intelligible.

Aspects of the present disclosure overcome such challenges by detecting sounds of different categories to identify whether or when dialogues or speeches are the primary content being played. In some aspects, a machine learning model is sued to detect or identify different sound categories. To facilitate understanding, aspects of the present disclosure implement a smooth transition to a speech enhancing equalization profile so that users may better understand the meanings therein. When the speech content is over, aspects of the present disclosure provide that the playback smoothly transitions to the original or another preferred equalization profile.

Dialogues may often suffer from a lack of clarity in audio-for-video (A4V) content. To improve dialogue clarity, sound products (e.g., speakers, sound bars, headphones, etc.) may include a pre-configured equalization mode that enhances the dialogue or speech clarity. When a dialogue equalization mode is turned on, non-dialogue audio quality may be negatively impacted. However, due to interlacing with other non-dialogue content, a user may not timely or practically turn on the dialogue mode at a proper time (e.g., multiple different occasions in a same playback session).

The present disclosure provides benefits of an improved (e.g., better sounding) dialogue equalization mode. In general, automatic equalization of audio content to enhance speech in the content as variously described herein allows for the equalization to be applied when speech is detected, thereby making the application of the speech-enhancing equalization dynamic based on the content itself, as opposed to not having the equalization turned on or off in a static manner. This allows for various benefits such as more aggressive/desirable speech enhancement and/or more aggressive/desirable equalization of non-speech content (e.g., enhancing bass in action scenes of a movie or applying a music-enhancing equalization when music is being played). In other words, the dialogue enhancing variously described herein can be applied only when one or more predefined conditions are met to indicate that there is a known or high confidence that there is actual speech in the audio content. One example method of determining whether audio being played includes speech (or is about to include speech, which can be determined by pre-processing of the audio data shortly before it is to be played) is using an algorithm, such as a trained machine-learning model. By implementing machine learning that detects actual speech/dialogue, dialogue tuning may be implemented as needed (e.g., in view of background sound and surrounding noises). By using machine learning and artificial intelligence in the dialogue recognition models, aspects of the present disclosure significantly reduce misapplication of dialogue mode to non-dialogue mode, resulting in an improvement of audio performance for music or action scenes. The automatic aspect of implementing the present disclosure requires minimal input from the user and improves overall dialogue intelligibility.

In aspects, a deep learning model estimates multiple energy levels in the media audio content in real-time. The energy levels may include speech energy, music energy, and singing energy. The system may also calculate ratios of different sound categories compared to the total energy in the content signal for identifying a predominant sound category.

The deep learning model (e.g., artificial intelligence) may be trained, so that the determination of sound categories is not pre-programmed, but determined based on machine learning. In one example, in order to train the deep learning model, data is synthesized in order to emulate A4V content. The A4V content may be emulated by mixing separate tracks of music, speech, sound effects, and singing. With these energy levels, control logic is applied to seamlessly fade or transition in and out of the dialogue mode.

In addition to categorizing content type, the deep learning model may also be trained for content understanding (e.g., what the content is in addition to what category such content belongs to). For example, in addition to estimating the music or singing energy level, the sounds of musical instruments used may also be estimated. In some cases, a music or video genre classifier may also be included in the deep learning model to determine if the sound may belong to hip-hop or an action movie.

Based on the detection of content, aspects of the present disclosure may improve control logic for the playback device. For example, in addition to the output of the deep learning models, system states, such as volume level and subwoofer availability may also be output. Environmental noise monitoring may also be implemented to improve the control logic (e.g., for active noise cancellation).

The detection and/or measurement information may be used to compute the equalization profile of the dialogue mode. As such, a comprehensive machine learning model that estimates speech saliency or intelligibility may be applied.

In aspects, the deep learning model is trained to calculate a level of confidence for a determined content category. For example, the deep learning model may output a measure of confidence that the content is, for example, speech or not-speech. The confidence parameter may help to control aspects of changes in equalizations for the user's benefit. As an example, when the model indicates a sudden high probability, or level of confidence, that the detected sound is speech, the time constants in the ballistics in switching equalization may occur quickly, in an effort to switch to the speech mode as quickly as possible. Additionally or alternatively, in aspects, the level of confidence of a determined content category influences how much of an equalization change is implemented. As an example, if the maximum change in the center of a channel is 4 dB, and the model indicates a high level of confidence the content category is speech, the control logic may add a full 4 dB for output by the playback device. If the maximum change in the center of a channel is 4 dB, and the model indicates a low level of confidence the content category is speech, the control logic may apply less than the full 4 dB for output by the playback device. In this manner, the amount of adjustment is based, at least in part, on the confidence level of the model.

In some cases, to improve sound quality, speech clarity, and specialization, the deep learning model detects or recognizes sources in the audio signal and separates or extracts certain sources or types of content for particular output channels. For example, the speech content may be extracted from the rest of the soundtrack and played at a pair of synchronized open audio headphones. This way, surround sound is maintained enabling the user to have a clear understanding of the speech content.

In some cases, aspects of the present disclosure apply to various speakers in different surroundings, including automotive audio, portable speakers, headphones, ear buds, and the like, as described below.

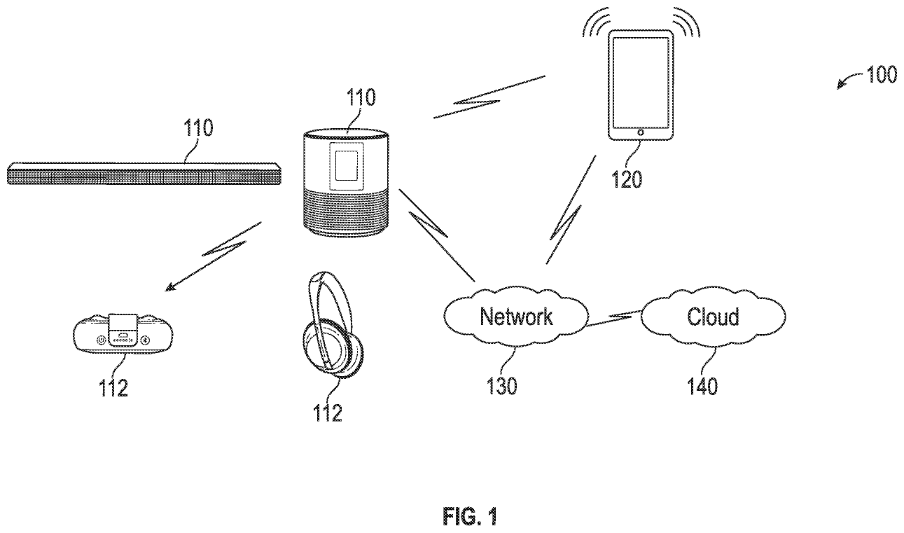

FIG. 1 illustrates an example system 100 in which aspects of the present disclosure are practiced. As shown, system 100 includes one or more sound processing and playback devices 110 (e.g., a wireless audio device, such as a sound bar or a smart speaker) communicatively coupled with a source device 120 (e.g., a computing device or user device, such as a smartphone, tablet computer, or the like). One or more partner devices 112 (e.g., a portable speaker, a headset, or the like) may be available to accept pairing requests from the sound processing and playback device 110 or the source device 120. The sound processing and playback device 110 may be paired with the source device 120 and may receive content data (including audio signal) from the source device 120. The sound processing and playback device 110 may also receive content data directly from the network 130. The partner device 112 may be battery-powered portable devices suitable for mobile or privacy applications.

According to aspects of the present disclosure, the sound processing and playback device 110 may receive an original set of audio signals from at least one of the source device 120, the network 130, or the cloud 140 (via the network 130). The content of the audio signals is analyzed prior to playback to determine whether one or more predefined conditions are met to indicate that the content includes speech. The analysis can use various different techniques, such as using a trained machine-learning model as described herein, analyzing metadata associated with the content (e.g., where the metadata indicates that the content includes speech), analyzing a voice track of the audio signal (where one exists), analyzing different channels of the audio signal, and/or other techniques as can be understood based on this disclosure. Techniques that utilize metadata associated with the audio signal and/or its contents can analyze the metadata shortly before playback to determine whether the metadata indicates that the audio content includes speech or otherwise meets predefined conditions, and if so, a speech/dialogue enhancing equalization (as variously described herein) can be automatically applied to assist with intelligibility of the speech. The metadata could be in the form of text related to the audio content (such as closed captioning data or other subtitling), genre data (such as indicating the content is a podcast or talk show), and/or other data to help determine whether speech is included in the content. If the audio signal or related content includes a voice track, the energy level of the voice track could be analyzed to determine whether the audio content includes speech. If the audio signal includes different channels, they could be analyzed and/or compared to determine whether speech is likely occurring. For instance, such analysis could include comparing correlated content between two channels (such as the correlated content between left and right channels of a stereo audio signal) and/or analyzing the center channel (e.g., in a 5.0, 5.1, 7.0, or 7.1 audio signal), as the center channel is typically where a majority of the dialogue from movies and television occurs. For example, center channel analysis could include determining when the center channel playback exceeds a threshold (e.g., nominal threshold or relative-to-other-channel(s) threshold) to determine that the content likely includes speech and so the speech enhancement equalization should be automatically applied. Numerous different techniques will be apparent in light of this disclosure.

In response to determining the one or more predefined conditions are met, a first playback equalization configured to enhance the speech within the content is automatically applied. As described herein, automatically may mean absent user input. Therefore, in response to determining the one or more predefined conditions are met, a first playback equalization configured to enhance the speech within the content is applied without user input.

In aspects, applying the first playback equalization to the audio signal includes a transition to the first playback equalization from either the no playback equalization or the second playback equalization. The transition includes a gradual change from either the no playback equalization or the second playback equalization to the first playback equalization. In aspects, the second playback equalization includes low frequency enhancement and/or music playback enhancement.

In aspects, applying the first playback equalization to the audio signal includes increasing a volume of the speech within the content relative to other content within the audio signal. In aspects, the speech content is extracted using a machine-learning algorithm. Additionally or alternatively, in aspects, the speech content is taken from at least one of correlated content between two channels or a center channel (as described above). In aspects, the speech content is taken from a speech component of the audio signal.

In aspects, applying the first playback equalization to the audio signal includes decreasing a volume of non-speech content within the audio signal. In aspects, in addition to decreasing the volume of non-speech content, the volume of the speech within the content is increased.

In aspects, the second playback equalization includes enhancing the low frequency components of the content and/or enhancing music playback of the content.

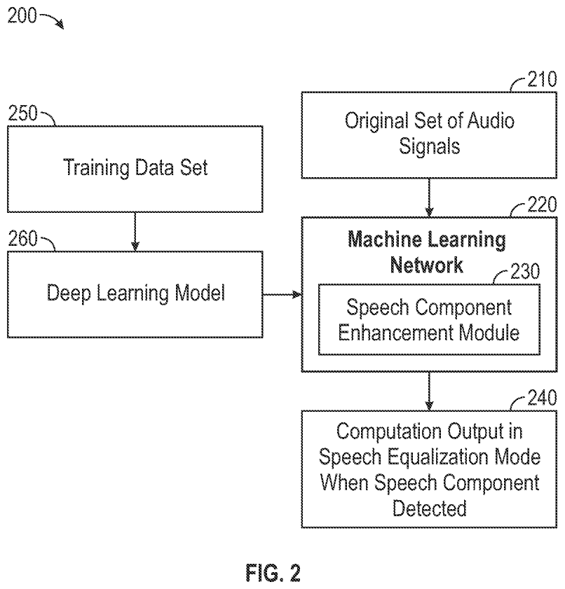

In some aspects, the sound processing and playback device 110 may analyze the original set of audio signals and detect for a speech component using a trained machine-learning network (e.g., the deep learning model 260 of FIG. 2). The machine-learning network is trained to identify speech components based on mixed categories of audio content, such as dialogues, music, singing, and other sound categories (e.g., instrumental or digital sound effects). The speech component may include any sound element that carries linguistic meaning(s).

Upon detecting the speech component, the sound processing and playback device 110 may enhance the detected speech component by transitioning from an original equalization mode to a speech (or dialogue) equalization mode. The speech equalization mode may enable a user to better understand the linguistic meanings in the speech component. For example, the speech equalization mode may enhance the frequency spectrums related to dialogue and/or suppress non-speech frequency spectrums. When the sound processing and playback device 110 does not detect the speech component or the detected speech component has disappeared or discontinued in the incoming audio signals, the sound processing and playback device 110 may output the original set of audio signals in the original equalization mode. As such, the sound processing and playback device 110 intelligently applies the speech equalization mode only when needed, achieving both speech enhancement and minimizing negative impact to non-speech audio content.

In certain scenarios, the playback device 110 provides different volume settings for different frequency bands. Dynamic equalization may adjust the overall system frequency response as a function of a detected mode and may provide a loudness compensation function that may de-emphasize lower bass content and emphasis treble content in an effort to improved volume-setting related intelligibility.

In aspects, the predicted sound pressure level (SPL) of the entire system is monitored and maintained as the playback device 110 switches between equalization modes. By monitoring the SPL, a similar SPL between the equalization two modes is maintained, which reduces the perceived volume change during non-dialog content.

The sound processing and playback device 110 can further include hardware and circuitry including processor(s)/processing system and memory configured to implement one or more sound management capabilities or other capabilities including, but not limited to, noise cancelling circuitry (not shown) and/or noise masking circuitry (not shown), body movement detecting devices/sensors and circuitry (e.g., one or more accelerometers, one or more gyroscopes, one or more magnetometers, etc.), geolocation circuitry and other sound processing circuitry.

In an aspect, the sound processing and playback device 110 is wirelessly connected to the source device 120 or the partner devices 112 using one or more wireless communication methods including, but not limited to, Bluetooth, Wi-Fi, Bluetooth Low Energy (BLE), other RF-based techniques, or the like. In an aspect, the sound processing and playback device 110 includes a transceiver that transmits and receives data via one or more antennae in order to exchange audio data and other information with the source device 120.

In an aspect, the sound processing and playback device 110 includes communication circuitry capable of transmitting and receiving audio data and other information from the source device 120. The sound processing and playback device 110 also includes an incoming audio buffer, such as a render buffer, that buffers at least a portion of an incoming audio signal (e.g., audio packets) in order to allow time for retransmissions of any missed or dropped data packets from the source device 120. For example, when the sound processing and playback device 110 receives Bluetooth transmissions from the source device 120, the communication circuitry typically buffers at least a portion of the incoming audio data in the render buffer before the audio is actually rendered and output as audio to at least one of the transducers (e.g., audio speakers) of the sound processing and playback device 110. This is done to ensure that even if there are RF collisions that cause audio packets to be lost during transmission, that there is time for the lost audio packets to be retransmitted by the source device 120 before they have to be rendered by the sound processing and playback device 110 for output by one or more acoustic transducers of the sound processing and playback device 110.

One example of the partner device 112 is shown as noise-canceling headphones; however, the techniques described herein apply to other wireless audio devices, such as wearable audio devices, including any audio output device that fits around, on, in, or near an ear (including open-ear audio devices worn on the head or shoulders of a user) or other body parts of a user, such as head or neck. The partner device 112 may take any form, wearable or otherwise, including standalone alone devices (including automobile speaker system), stationary devices (including portable devices, such as battery powered portable speakers), headphones, earphones, earpieces, headsets, goggles, headbands, earbuds, armbands, sport headphones, neckband, or eyeglasses with integrated speaker(s).

In an aspect, the sound processing and playback device 110 is connected to the source device 120 using a wired connection, with or without a corresponding wireless connection. The source device 120 can be a smartphone, a tablet computer, a laptop computer, a digital camera, or other user device that connects with the sound processing and playback device 110. As shown, the source device 120 can be connected to a network 130 (e.g., the Internet) and can access one or more services over the network. As shown, these services can include one or more cloud services 140.

In an aspect, the source device 120 can access a cloud server in the cloud 140 over the network 130 using a mobile web browser or a local software application or “app” executed on the source device 120. In an aspect, the software application or “app” is a local application that is installed and runs locally on the source device 120. In an aspect, a cloud server accessible on the cloud 140 includes one or more cloud applications that are run on the cloud server. The cloud application can be accessed and run by the source device 120. For example, the cloud application can generate web pages that are rendered by the mobile web browser on the source device 120. In an aspect, a mobile software application installed on the source device 120 or a cloud application installed on a cloud server, individually or in combination, may be used to implement the techniques for low latency Bluetooth communication between the source device 120 and the sound processing and playback device 110 in accordance with aspects of the present disclosure. In an aspect, examples of the local software application and the cloud application include a gaming application, an audio AR application, and/or a gaming application with audio AR capabilities. The source device 120 may receive signals (e.g., data and controls) from the sound processing and playback device 110 and send signals to the sound processing and playback device 110.

An example sound processing and playback device 110 or the partner device 112 may include components (not shown in FIG. 1) described below. For example, the sound processing and playback device 110 or the partner device 112 may each include one or more processors, memory modules, communication modules, and/or input interfaces for receiving user input. The sound processing and playback device 110 or the partner device 112 may each include one or more electro-acoustic transducers (or speakers) for outputting audio. The sound processing and playback device 110 also includes a user input interface. The user input interface can include a plurality of preset indicators, which can be hardware buttons. The preset indicators can provide the user with easy, one press access to entities assigned to those buttons. The assigned entities can be associated with different ones of the digital audio sources such that a single sound processing and playback device 110 can provide for single press access to various different digital audio sources.

The sound processing and playback device 110 or the partner device 112 may inherently include an acoustic driver or speaker to transduce audio signals to acoustic energy through the audio hardware. The sound processing and playback device 110 also includes a network interface, at least one processor, audio hardware, power supplies for powering the various components of the sound processing and playback device 110, and memory. In an aspect, the processor, the network interface, the power supplies, and the memory are interconnected using various buses, and several of the components can be mounted on a common motherboard or in other manners as appropriate. In some cases, the sound processing and playback device 110 or the partner device 112 may include an enclosure that houses an optional graphical interface (e.g., an OLED display) which can provide the user with information regarding currently playing (“Now Playing”) music.

A network interface may provide for communication between the sound processing and playback device 110 and other electronic user devices, such as the source device 120 and the partner device 112, via one or more communications protocols, such as Bluetooth classic protocol, Bluetooth low energy protocol, and others. In general, the network interface provides either or both of a wireless network interface and a wired interface (optional). The wireless interface allows the sound processing and playback device 110 to communicate wirelessly with other devices in accordance with a wireless communication protocol such as IEEE 802.11. The wired interface provides network interface functions via a wired (e.g., Ethernet) connection for reliability and fast transfer rate, for example, used when the sound processing and playback device 110 is not worn by a user.

In certain aspects, the network interface includes a network media processor for supporting Apple AirPlay® and/or Apple Airplay® 2. For example, if a user connects an AirPlay® or Apple Airplay® 2 enabled device, such as an iPhone or iPad device, to the network, the user can then stream music to the network connected audio playback devices via Apple AirPlay® or Apple Airplay® 2. Notably, the audio playback device can support audio-streaming via AirPlay®, Apple Airplay® 2 and/or DLNA's UPnP protocols, and all integrated within one device.

All other digital audio received as part of network packets may pass straight from the network media processor through a USB bridge (not shown) to the processor and runs into the decoders, DSP, and eventually is played back (rendered) via the electro-acoustic transducer(s).

The network interface can further include a Bluetooth circuitry for Bluetooth applications (e.g., for wireless communication with a Bluetooth enabled audio source such as a smartphone or tablet) or other Bluetooth enabled speaker packages. In some aspects, the Bluetooth circuitry may be the primary network interface due to energy constraints. For example, the network interface may use the Bluetooth circuitry solely for mobile applications when the sound processing and playback device 110 or the partner device 112 adopts any wearable form. For example, BLE technologies may be used in the sound processing and playback device 110 or the partner device 112 to extend battery life, reduce package weight, and provide high quality performance without other backup or alternative network interfaces.

In an aspect, the network interface supports communication with other devices using multiple communication protocols simultaneously at one time. For instance, the sound processing and playback device 110 can support Wi-Fi/Bluetooth coexistence and can support simultaneous communication using both Wi-Fi and Bluetooth protocols at one time. For example, the sound processing and playback device 110 can receive an audio stream from a smart phone using Bluetooth and can further simultaneously redistribute the audio stream to one or more other devices over Wi-Fi. In an aspect, the network interface may include only one RF chain capable of communicating using only one communication method (e.g., Wi-Fi or Bluetooth) at one time. In this context, the network interface may simultaneously support Wi-Fi and Bluetooth communications by time-sharing the single RF chain between Wi-Fi and Bluetooth, for example, according to a time division multiplexing (TDM) pattern.

Streamed data may pass from the network interface to the processor. The processor can execute instructions (e.g., for performing, among other things, digital signal processing, decoding, and equalization functions), including instructions stored in the memory. The processor can be implemented as a chipset of chips that includes separate and multiple analog and digital processors. The processor can provide, for example, for coordination of other components of the audio sound processing and playback device 110, such as control of user interfaces.

A memory may store software/firmware related to protocols and versions thereof used by the sound processing and playback device 110 or the partner device 112 for communicating with other networked devices, including the source device 120. For example, the software/firmware governs how the sound processing and playback device 110 communicates with other devices for synchronized playback of audio. In an aspect, the software/firmware includes lower level frame protocols related to control path management and audio path management. The protocols related to control path management generally include protocols used for exchanging messages between speakers. The protocols related to audio path management generally include protocols used for clock synchronization, audio distribution/frame synchronization, audio decoder/time alignment, and playback of an audio stream. In an aspect, the memory can also store various codecs supported by the speaker package for audio playback of respective media formats. In an aspect, the software/firmware stored in the memory can be accessible and executable by the processor for synchronized playback of audio with other networked speaker packages.

In aspects, the protocols stored in the memory may include BLE according to, for example, the Bluetooth Core Specification Version 5.2 (BT5.2). The sound processing and playback device 110 or the partner device 112, and the various components therein, are provided herein to sufficiently comply with or perform aspects of the protocols and the associated specifications. For example, BT5.2 includes enhanced attribute protocol (EATT) that supports concurrent transactions. A new L2CAP mode is defined to support EATT. As such, the sound processing and playback device 110 includes hardware and software components sufficiently to support the specifications and modes of operations of BT5.2, even if not expressly illustrated or discussed in this disclosure. For example, the sound processing and playback device 110 may utilize LE Isochronous Channels specified in BT5.2.

The processor may provide a processed digital audio signal to the audio hardware which includes one or more digital-to-analog (D/A) converters for converting the digital audio signal to an analog audio signal. The audio hardware also includes one or more amplifiers which provide amplified analog audio signals to the electroacoustic transducer(s) for sound output. In addition, the audio hardware can include circuitry for processing analog input signals to provide digital audio signals for sharing with other devices, for example, other speaker packages for synchronized output of the digital audio.

The memory can include, for example, any non-transitory memory such as flash memory and/or non-volatile random access memory (NVRAM). In some aspects, instructions (e.g., software) are stored in an information carrier. The instructions, when executed by one or more processing devices (e.g., the processor), perform one or more processes, such as those described elsewhere herein. The instructions can also be stored by one or more storage devices, such as one or more computer or machine-readable mediums (for example, the memory, or memory on the processor). The instructions can include instructions for performing decoding (i.e., the software modules include the audio codecs for decoding the digital audio streams), as well as digital signal processing and equalization. In certain aspects, the memory and the processor may collaborate in data acquisition and real time processing with microphones on the sound processing and playback device 110 or the source device 120.

### Example Intelligent Dialogue or Speech Enhancement

Aspects of the present disclosure provide techniques for intelligently detecting and enhancing a detected speech component in an audio signal. For example, an audio device may detect, in an original set of audio signals, a speech component using any number of methods. In one example, a trained machine-learning network based on mixed categories of audio content. The speech component includes sound elements that carry linguistic meanings. The audio device may enhance the detected speech component by transitioning from an original equalization mode to a speech equalization mode that enables a user to better understand the linguistic meanings of the speech. Absent the detection of the speech component (e.g., before or after the detection of the speech component), the audio device may output the original set of audio signals in the original equalization mode. In order to correctly detect the speech component (e.g., as opposed to, for example, a singing component), the machine-learning network may be trained to recognize what constitutes speech without user intervention. An example intelligent dialogue or speech enhancement according to the present disclosure is provided in FIG. 2.

FIG. 2 is a block diagram 200 illustrating relationships between audio signals, training data set, and processing components, in accordance to aspects of the present disclosure. As shown, the original set of audio signals 210, such as received by the sound processing and playback device 110, is provided to the machine learning network 220. For example, the sound processing and playback device 110 may be communicatively coupled with the machine learning network 220 via the network 130.

The machine learning network 220 may analyze the original set of audio signals 210 using the deep learning model 260, which is coupled with the machine learning network 220. Although FIG. 2 illustrates the deep learning model 260 as being separate from the machine learning network 220, in some cases, the deep learning model 260 may be integrated with the machine learning network 220. Although FIG. 2 illustrates one deep learning model 260 being coupled with the machine learning network 220, in some cases, two or more different deep learning models may be coupled with or integrated with the machine learning network 220. In some cases, the machine learning network 220 or its interface (e.g., a graphical user interface, such as an application on an operating system) may be installed on the source device 120, which may be a smartphone.

The deep learning model 260 may use various machine learning techniques based on artificial neural networks. For example, the deep learning model 260 may include deep learning architectures, such as deep neural networks, deep belief networks, deep reinforcement learning, recurrent neural networks, convolutional neural networks, and the like. Similar to speech recognition, the deep learning model 260 may identify sound elements that include linguistic meanings. On the other hand, the deep learning model 260 is trained to distinguish sound elements that primarily express linguistic meanings versus sound elements that primarily express tonal or musical elements other than linguistic meanings in contexts.

For example, the deep learning model 260 is trained to distinguish a speech component from a music component or a singing component. The speech component may include sounds in which meanings are conveyed based on linguistic characteristics. The music component may include sounds that lack linguistic characteristics. The singing component may include a mixture of sounds that simultaneously includes a component of linguistic expressions and a component of musical expressions.

The deep learning model 260 is trained, based on the training data set 250, to identify sounds that does not include musical expressions or lacking linguistic characteristics. For example, the training data set 250 may include various types of singing, music, and dialogues. The deep learning model 260 may be supervised, semi-supervised, or unsupervised to learn whether a pattern of sounds belong to one of the three categories. For example, the training data set 250 may include various samples, such as music, opera, rap music, chorus, conversations, dialogues, speeches, and the like.

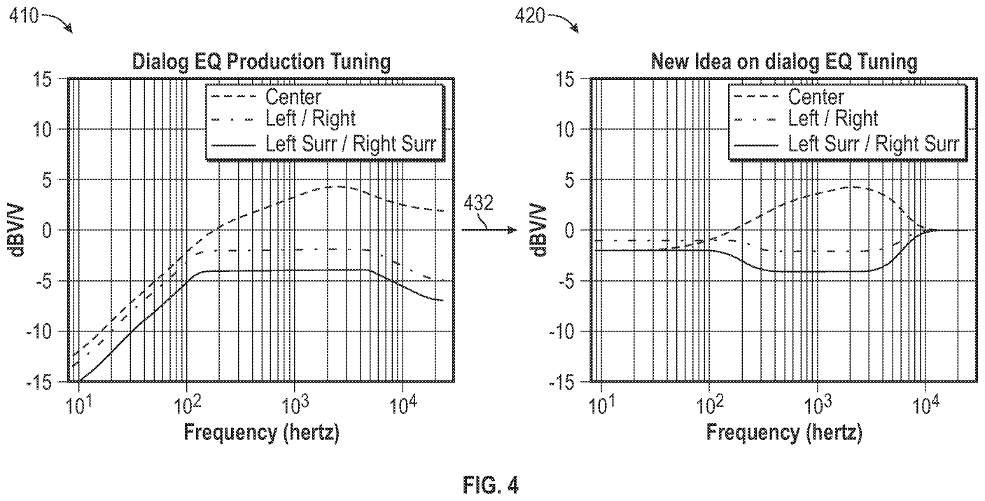

The machine learning network 220 may then use the deep learning model 260 to calculate a root mean square of respective energy levels of each category of the mixed categories of audio content. For example, the deep learning model 260 may estimate the respective energy levels of each category of the mixed categories of audio content. The mixed categories of audio content may include the speech component, the music component, and the singing component, which may correspond to the samples included in the training data set 250. FIG. 5 and corresponding description below provide further details of the training data set 250 below.

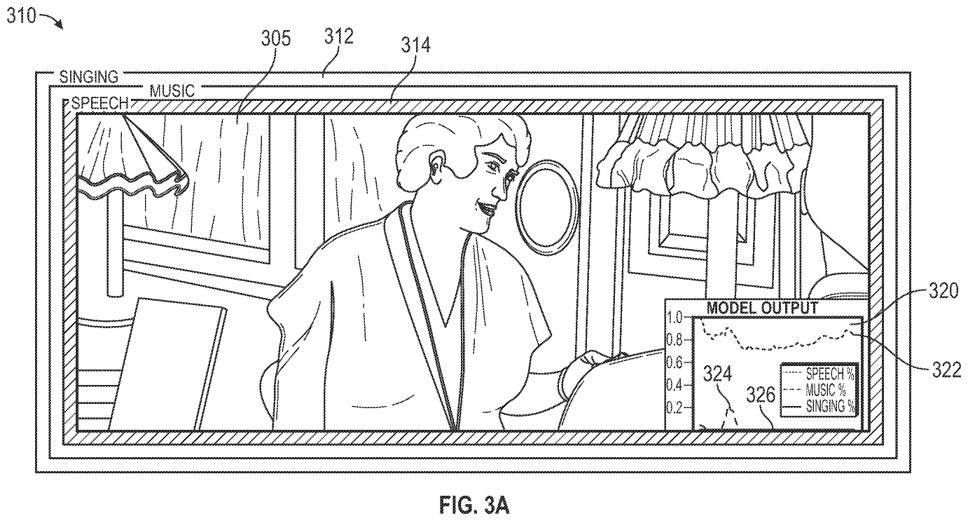

The speech component may be defined or detected by determining a ratio of an energy level of the speech component and an overall energy level exceeding a threshold value (examples illustrated in FIG. 3). In some cases, the trained machine-learning network 220 is trained to identify the respective category of the mixed categories of audio content and the threshold value based on a known database of cinematic content (e.g., samples in the training data set 250).

The machine learning network 220 may include a speech component enhancement module 230. The machine learning network 220 computes and provides the computation output 240 in the speech equalization mode when speech component is detected.

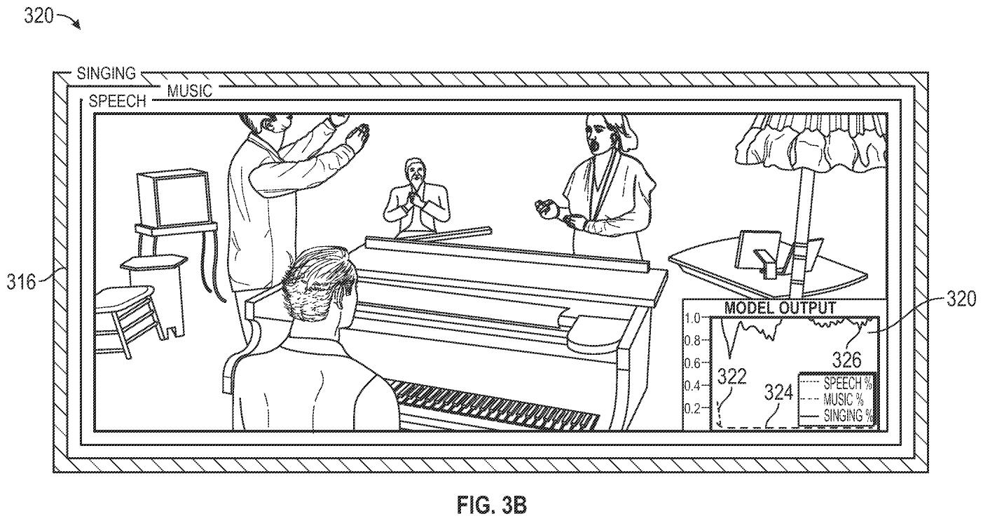

The speech component enhancement module 230 may implement the speech equalization mode as well as be trained to improve the speech equalization mode. For example, the speech component enhancement module 230 may increase a magnitude or a contrast of speech related frequency bands to improve the intelligibility of the speech component. In some cases, the speech component enhancement module 230 decreases the magnitude of non-speech related frequency bands or signal channels. In some cases, the speech component enhancement module 230 alters or updates an equalization setting or a dynamic range compression setting on the non-speech related frequency bands or signal channels. The speech component enhancement module may combine two or more of these operations. An example of a speech equalization mode is provided in FIG. 4 and described below.

### Example Dialogue or Speech Detection

FIGS. 3A and 3B illustrate an example determination of different sound categories in audio signals, in accordance with certain aspects of the present disclosure. FIG. 3A shows a first instance 310 and FIG. 3B shows a second instance 320 of a video clip 305. In the first instance, a character in the video clip is speaking. The window includes a category indication frame 312 that monitors the currently detected categories of sound (e.g., singing, music, and speech). The window of the first instance 310 has the frame 314 indicating a speech component highlighted while the window of the second instance 320 has the frame 316 indicating a singing component highlighted. Such indications may be useful for supervised learning so that a trainer may verify whether the machine learning network 220 has categorized the sound content correctly.

FIGS. 3A and 3B further show a data processing window 320 in each of the video windows. The data processing window 320 plots the computed model output, such as energy levels, for each of the sound categories. For example, in the data processing window 320 of the first instance 310, the root mean square of energy level of the speech component 322 is predominant in the output. The root mean squares of energy levels of the music component 324 and the singing component 326 are low. In some cases, the ratio of the energy level of the speech component and the overall energy level may be compared with a threshold level (learned based on data sets). The speech component is detected when the ratio exceeds the threshold value. Therefore, in the first instance 310, the machine learning network 220 detects the speech component and indicates the detection by highlighting the frame 314 which corresponds to singing.

In the data processing window of second instance 320, the root mean square of energy level of the singing component 326 is predominant in the output, while the root mean squares of energy levels of the music component 324 and the speech component 322 are low. Therefore, in the second instance 320, the machine learning network 220 detects the singing component and indicates the detection by highlighting the frame 316 which corresponds to singing.

Although FIGS. 3A and 3B illustrate examples of energy determination for three categories of sounds, a different set of categories may be used. For example, the machine learning network 220 may further be trained to identify noises that do not belong to any of the speech, music, or singing categories. According to aspects of the present disclosure, detecting and identifying noises may allow the machine learning network 220 to receive and process environmental noises captured for active noise cancellation. The noise category may also improve the accuracy in detecting other sound categories.

### Example Dialogue or Speech Processing

Upon detecting the speech component, the machine learning network 220 may enhance the detected speech component by transitioning from an original equalization mode to a speech equalization mode. FIG. 4 illustrates an example of such equalization processing. An original equalization mode 410 (which may alternatively be no equalization mode) is transitioned (via the process 432) to a speech equalization mode 420 when a speech component is detected and dominant in the content (e.g., excluding background speech noise). As shown, in the original equalization mode 410, three profiles are used for tuning the center, left/right, and left surround/right surround channels. Before transitioning to the speech equalization mode 420, the bass and treble portions of all the channels have non-near-zero amplifications, in order to provide a rich surround sound. Dialogues or speeches in such equalization mode may be difficult to understand given other sound components.

The process 432 implements a transition that minimizes the perceptibility of the change from the original equalization mode 410 (which again, may be no equalization mode) to the speech equalization mode 420. For example, the frequency band changes, the channel changes, or other various parameters may smoothly transition at different rates or different times, over different periods, to seamlessly blend the two equalization modes 410 and 420. In this manner, a user may not perceive the change. The process 432 may be performed by the speech component enhancement module 230 of FIG. 2.

In the second equalization mode 420, the base and the treble frequency spectrums of all three channels (center, sides, and surrounds) may be tuned to near-zero values as shown, thus allowing the spectrum range corresponding to speech frequencies to be more distinct from other non-speech sound components. As such, speech is more intelligible when played in the speech equalization mode 420 than in the original equalization mode 410.

### Example Training Data Set for Machine Learning

FIG. 5 illustrates an example process for generating training data set, such as the training data set 250 of FIG. 2, in accordance with certain aspects of the present disclosure. As an example, the training data set may be used by a deep learning model based on convolutional recurrent neural network (CRNN). The CRNN receives an input that is created by mixing multiple clean sound sources with certain noise for producing synthetic examples. In some cases, the input may take a format as Log Mel Spectrogram. As described in FIG. 2, the deep learning model may provide output for the energy levels of sounds of different categories. The output may include a number of frames that has a same time length in total as the input duration.

In some cases, the datasets for the deep learning model may be configured by the user to update or mix parameters of the datasets and/or parameters for the deep learning model. The training process may include closed-loop feedback (e.g., supervised), in which the model in training receives evaluation based on both the sound content detection and the equalization (e.g., speech and non-speech mode) output evaluation. For example, as shown in FIG. 5, four source datasets are used to produce the synthetic example 570. The speech dataset 510, music data set 520, singing dataset 530, and noise dataset 540 are mixed in different manners to form a first sound category 550 and a second sound category 560. The first sound category 550 includes all datasets 510-540, and emulates audios for videos. The second sound category 560 includes the singing dataset 530 and the noise dataset 540, emulating concert audios, or the like. The synthetic example 570 may choose one of the first and the second categories 550 or 560 for training the deep learning model.

### Methods and Processes for Intelligent Dialogue Enhancement

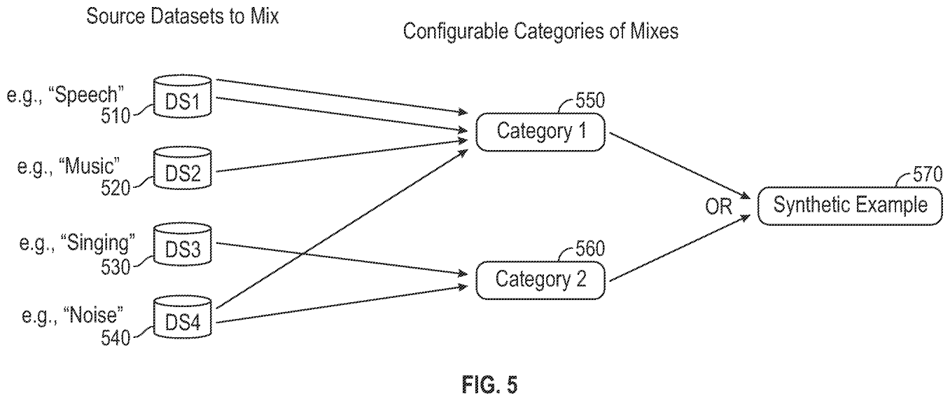

FIG. 6 is a flow diagram illustrating example operations 600 that may be performed by a target device for establishing wireless communications with other devices. For example, the example operations 600 may be performed by the sound processing and playback device 110 of FIG. 1.

The example operations 600 being at 602 by, during playback, analyzing content of the audio signal prior to the playback of the content to determine whether one or more predefined conditions are met to indicate that the content includes speech.

At 604, in response to determining the one or more predefined conditions are met, automatically applying to the audio signal a first playback equalization configured to enhance the speech within the content. Automatically applying the first playback equalization may refer to applying the first playback equalization without further input from the user.

At 606, in response to determining the one or more predefined conditions are not met, applying to the audio signal i) no playback equalization or ii) a second playback equalization different from the first playback equalization.

Notably, in aspects, the content is analyzed shortly prior to the playback of the audio signal as well as during the playback. This analysis may occur 20 ms to 2 seconds prior to the playback of the audio. In aspects, the analysis is more likely to occur in the 0.2 to 1 second rang. In aspects, the analysis occurs 0.5 seconds prior to playback. By analyzing content prior to playback as well as during playback, aspects of the present disclosure differ from pre-existing techniques that do not have the challenge of real time or near real time processing that comes with the disclosed techniques.

In aspects, and as described above, the analyzing is performed using a trained machine-learning model. In aspects, metadata associated with the content is analyzed wherein the metadata includes that the content includes speech. In aspects, when one or more predefined conditions exceed a threshold, a voice track of the audio signal is analyzed.

In aspects, different channels of the audio signals are analyzed. For example, content is correlated between two channels.

If the audio signal includes different channels, they could be analyzed and/or compared to determine whether speech is likely occurring. For instance, such analysis could include comparing correlated content between two channels (such as the correlated content between left and right channels of a stereo audio signal) and/or analyzing the center channel (e.g., in a 5.0, 5.1, 7.0, or 7.1 audio signal), as the center channel is typically where a majority of the dialogue from movies and television occurs. For example, center channel analysis could include determining when the center channel playback exceeds a threshold (e.g., nominal threshold or relative-to-other-channel(s) threshold) to determine that the content likely includes speech and so the speech enhancement equalization should be automatically applied.

According to aspects, applying of the first playback equalization to the audio signal includes transitioning to the first playback equalization from either i) the no playback equalization or ii) the second playback equalization. The transition may include a gradual change from either i) the no playback equalization or ii) the second playback equalization to the first playback equalization.

In aspects, applying of the first playback equalization to the audio signal includes increasing a volume of the speech within the content relative to other content within the audio signal. In aspects, the speech content is extracted using a machine-learning algorithm. As described herein, the speech content is taken from at least one of i) correlated content between two channels or ii) a center channel. In aspects, the speech content is taken from a speech component of the audio signal.

In aspects, applying of the first playback equalization to the audio signal includes decreasing a volume of non-speech content within the audio signal. Further, in aspects, the volume of the speech within the content is increased.

In aspects, the second playback equalization includes a low frequency enhancement, a music playback enhancement, or a combination of both.

In aspects, the sounds in the environment in which the audio signal is to be played back are analyzed to help determine whether to apply the first playback equalization to the audio signal.

In some aspects, the predefined conditions are configurable by a user. Additionally or alternatively, in some aspects, the first playback equalization can be configured by a user

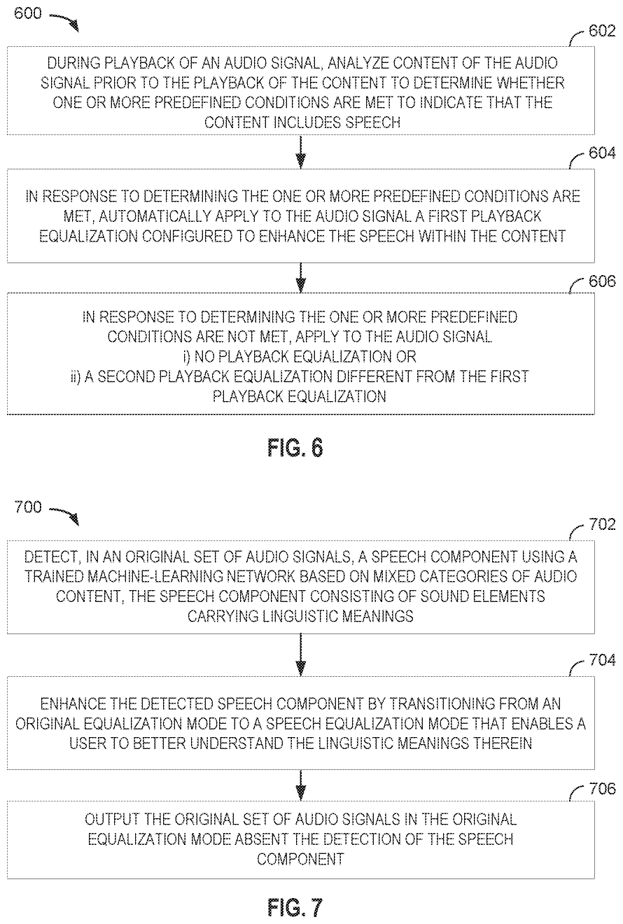

FIG. 7 is a flow diagram illustrating example operations 700 that may be performed by a target device for establishing wireless communications with other devices. For example, the example operations 700 may be performed by the sound processing and playback device 110 of FIG. 1.

The example operations 700 begin, at 702, by detecting, in an original set of audio signals, a speech component using a trained machine-learning network based on mixed categories of audio content, the speech component consisting of sound elements carrying linguistic meanings.

At 704, the detected speech component is enhanced by transitioning from an original equalization mode to a speech equalization mode that enables a user to better understand the linguistic meanings therein.

At 706, the original set of audio signals is output in the original equalization mode absent the detection of the speech component.

During operations, the performance of 704 and 706 depends on the instance of the content in the audio signals, which may vary from time to time. Thus, the enhancement performed at 704 may be dynamic and take place automatically to the speech component detected.

In aspects, the speech component may be detected using the trained machine-leaning network. For example, the detection may be based on calculating a root mean square of respective energy levels of each category of the mixed categories of audio content. In some cases, the trained machine-learning network may include a deep learning model that estimates the respective energy levels of each category of the mixed categories of audio content. The mixed categories of audio content may include the speech component, a music component, and a singing component.

In some cases, the speech component may be detected by determining a ratio of an energy level of the speech component and an overall energy level exceeding a threshold value. For example, the speech component may include sounds in which meanings are conveyed based on linguistic characteristics. The music component may include sounds that lack linguistic characteristics. The singing component may include a mixture of sounds that simultaneously includes a component of linguistic expressions and a component of musical expressions. In some cases, the trained machine-learning network may be trained to identify the respective category of the mixed categories of audio content and the threshold value based on a known database of cinematic content.

In some cases, the speech component may be detected by processing ongoing audio signals at an advanced time before the transitioning or outputting operations. For example, the processing or detection operations may be performed in real-time or near real-time with minimal delays allowed by the computational capacity of the handling device. In some cases, the processing device and the sound output device may be separate and independent from each other.

In aspects, enhancing the speech component may include fading from the original equalization mode into the speech equalization mode gradually. This way, the speech enhancement equalization may be engaged or initiated without being realized by the user. Similarly, the playback may include fading from the speech equalization mode back to the original equalization mode smoothly without being realized by the user. In some cases, the speech equalization mode may include at least one of: increasing a magnitude or a contrast of speech related frequency bands to improve intelligibility of the speech component; decreasing a magnitude of non-speech related frequency bands or signal channels; or altering an equalization setting or a dynamic range compression setting on the non-speech related frequency bands or signal channels.

In aspects, enhancing the detected speech component may be performed in a first device and outputting the original set of audio signals is performed in a second device. For example, the first device may include a sound bar configured to output a surround sound (e.g., the sound processing and playback device 110 of FIG. 1); and the second device may include a noise-canceling headphone (e.g., the partner device 112 of FIG. 1). As such, when the sound bar receives audio signal, the sound bar performs computations (e.g., aided by machine learning and neural network computation as described earlier) for detecting speech component and automatically apply speech mode equalization. The output of the speech mode enhancement may be performed by the sound bar or the noise-canceling headphone, or both. The first device and the second device may be paired in a short-range wireless communication network.

In some cases, the first device may be a noise-canceling headphone while the second device may be a sound bar configured to output a surround sound. The first device and the second device may each include different devices, such as smart phones or other types of wearable electronic devices. Accordingly, various configurations based on different devices may be configured.

In aspects, the detected speech component may be extracted and separately played in a third device (e.g., another short-range paired speaker or noise-canceling headphone, such as a second partner device 112 of FIG. 1). In some cases, the extracted speech component may be used to improve the equalization profile, such as by identifying certain frequency spectrums for processing in the equalizer. In some cases, the first device, the second device, and the third device are configured to produce a mixed surround sound. For example, the different devices may each have an equalization profile for a respective category of sound, such as speech, singing, and background music. In some cases, one or more of the devices may include a microphone or a noise sensor for noise canceling. The devices may be paired with a microphone for measuring surrounding noises for cancellation.

In aspects, the original set of audio signals may be played or output without speech content enhancement based on a determination of a disappearance of the speech component. For example, in a multimedia clip that includes occasional speech or dialogue content, the speech enhancement processing may apply only to the portions where speech content is detected.

In aspects, the disclosed methods are applicable to wireless earbuds, earhooks, or ear-to-ear devices. For example, a host like a mobile phone may be connected over Bluetooth to a bud (e.g., right side) and that right-side bud further connects to the left-side bud using either a Bluetooth link or using other wireless technologies like NFMI or NFEMI. The left-side bud is first time-synchronized with the right-side bud. Audio frames (compressed in mono) are sent from the left-side bud with its timestamp (which is synchronized with the right bud's timestamp) as described in the technology above. The right bud will forward these encoded mono frames along with its own frames. The right bud will not wait for an audio frame from the left bud with the same timestamp. Instead, the right-bud sends whatever frame is available and ready to be sent with suitable packing. It is the responsibility of the receiving application in the host to assemble the packets using the timestamp and the channel number. The receiving application, depending upon how it is configured, can choose to merge the decoded mono channel of one bud and a decoded mono channel of the other bud into a stereo track based on the timestamp included in the header of the received encoded frames. The present disclosure allows the right-side bud to simply forward the audio frames from the left-side bud without decoding the frame. This helps to conserve battery power in truly wireless audio devices.

In some aspects, the techniques variously described herein can be used to determine contextual information for a source device and/or the user of the source device. For instance, the techniques can be used to help determine aspects of the user's environment (e.g., noisy location, quiet location, indoors, outdoors, on an airplane, in a car, etc.) and/or activity (e.g., commuting, walking, running, sitting, driving, flying, etc.). In some such aspects, the sensor data received from the source device can be processed at the target device to determine such contextual information and provide new or enhanced experiences to the user. For example, this could enable playlist or audio content customization, noise cancellation adjustment, and/or other settings adjustments (e.g., audio equalizer settings, volume settings, notification settings, etc.), to name a few examples. As source devices (e.g., headphones or earbuds) typically have limited resources (e.g., memory and/or processing resources), using the techniques described herein to offload the processing of data from sensors of the source device(s) to a target device while having a system to synchronize the sensor data at the target device provides a variety of applications. In some aspects, the techniques disclosed herein enables the user device to automatically identify an optimized or a most favorable configuration or setting for the synchronized audio capture operations.

In some aspects, the techniques variously described herein can be used for a multitude of audio/video applications. For instance, the techniques can be used for stereo or surround sound audio capture from a source device to be synchronized at a target device with video captured from the same source device, another source device, and/or the target device. For example, the techniques can be used to synchronize stereo or surround sound audio captured by microphones on a pair of headphones with video captured from a camera on or connected to the headphones, a separate camera, and/or the camera of a smartphone, where the smartphone (which is the target device in this example) performs the synchronization of the audio and video. This can enable real-time playback of stereo or surround sound audio with video (e.g., for live streaming), capture for recorded videos with stereo or surround sound audio (e.g., for posting to social media platforms or news platforms). In addition, the techniques described herein can enable wireless captured audio for audio or video messages without interrupting a user's music or audio playback. Thus, the techniques described herein enable the ability to produce immersive and/or noise-free audio for videos using a wireless configuration. Moreover, as can be understood based on this disclosure, the techniques described enable schemes that were only previously achievable using a wired configuration, so the techniques described free the user from the undesirable and uncomfortable experience of being tethered by one or more wires.

It can be noted that, descriptions of aspects of the present disclosure are presented above for purposes of illustration, but aspects of the present disclosure are not intended to be limited to any of the disclosed aspects. Many modifications and variations will be apparent to those of ordinary skill in the art without departing from the scope and spirit of the described aspects.

In the preceding, reference is made to aspects presented in this disclosure. However, the scope of the present disclosure is not limited to specific described aspects. Aspects of the present disclosure can take the form of an entirely hardware aspect, an entirely software aspect (including firmware, resident software, micro-code, etc.) or an aspect combining software and hardware aspects that can all generally be referred to herein as a “component,” “circuit,” “module” or “system.” Furthermore, aspects of the present disclosure can take the form of a computer program product embodied in one or more computer readable medium(s) having computer readable program code embodied thereon.

Any combination of one or more computer readable medium(s) can be utilized. The computer readable medium can be a computer readable signal medium or a computer readable storage medium. A computer readable storage medium can be, for example, but not limited to, an electronic, magnetic, optical, electromagnetic, infrared, or semiconductor system, apparatus, or device, or any suitable combination of the foregoing. More specific examples a computer readable storage medium include: an electrical connection having one or more wires, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the current context, a computer readable storage medium can be any tangible medium that can contain, or store a program.

The flowchart and block diagrams in the Figures illustrate the architecture, functionality and operation of possible implementations of systems, methods and computer program products according to various aspects. In this regard, each block in the flowchart or block diagrams can represent a module, segment or portion of code, which comprises one or more executable instructions for implementing the specified logical function(s). In some alternative implementations the functions noted in the block can occur out of the order noted in the figures. For example, two blocks shown in succession can, in fact, be executed substantially concurrently, or the blocks can sometimes be executed in the reverse order, depending upon the functionality involved. Each block of the block diagrams and/or flowchart illustrations, and combinations of blocks in the block diagrams and/or flowchart illustrations can be implemented by special-purpose hardware-based systems that perform the specified functions or acts, or combinations of special purpose hardware and computer instructions.

What is claimed is:

1. A method for audio signal processing, the method comprising:
during playback of an audio signal, analyzing content of the audio signal prior to the playback of the content to determine whether one or more predefined conditions are met to indicate that the content includes speech;
in response to determining the one or more predefined conditions are met, automatically applying to the audio signal a first playback equalization configured to enhance the speech within the content; and
in response to determining the one or more predefined conditions are not met, applying to the audio signal i) no playback equalization or ii) a second playback equalization different from the first playback equalization.

2. The method of claim 1, wherein the analyzing is performed using a trained machine-learning model.

3. The method of claim 2, wherein the trained machine-learning model comprises a deep learning model that estimates energy levels of the audio signal.

4. The method of claim 3, wherein the energy levels of the audio signals include energy levels of any combination the speech, a music component of the audio signal, and a singing component of the audio signal.

5. The method of claim 1, wherein the analyzing comprises analyzing metadata associated with the content and wherein the metadata indicates that the content includes speech.

6. The method of claim 1, wherein the analyzing comprises analyzing a voice track of the audio signal, wherein the one or more predefined conditions includes the voice track exceeding a threshold value.

7. The method of claim 1, wherein the audio signal comprises different channels and the analyzing comprises analyzing the different channels.

8. The method of claim 7, wherein analyzing the different channels comprises comparing correlated content between two channels of the different channels.

9. The method of claim 1, wherein the analyzing comprises analyzing the center channel of the audio signal.

10. The method of claim 1, wherein automatically applying to the audio signal the first playback equalization configured to enhance the speech within the content comprises transitioning to the first playback equalization from either i) no playback equalization or ii) the second playback equalization.

11. The method of claim 1, wherein automatically applying to the audio signal the first playback equalization configured to enhance the speech within the content comprises increasing a volume of the speech within the content relative to other content within the audio signal.

12. The method of claim 1, wherein automatically applying to the audio signal the first playback equalization configured to enhance the speech within the content comprises decreasing a volume of non-speech content within the audio signal.

13. The method of claim 12, further comprising increasing a volume of the speech within the content.

14. The method of claim 1, wherein the second playback equalization comprises at least one of low frequency enhancement or music playback enhancement.

15. The method of claim 1, wherein at least one of the first playback equalization or the one or more predefined conditions are configurable by a user.

16. The method of claim 1, further comprising analyzing sound in an environment in which the audio signal is to be played back to help determine whether to apply the first playback equalization to the audio signal.

17. An apparatus for audio signal processing, comprising:
a memory; and
a processor coupled with the memory, the processor and the memory configured to:
during playback of an audio signal, analyze content of the audio signal prior to the playback of the content to determine whether one or more predefined conditions are met to indicate that the content includes speech;
in response to determining the one or more predefined conditions are met, automatically apply to the audio signal a first playback equalization configured to enhance the speech within the content; and
in response to determining the one or more predefined conditions are not met, apply to the audio signal i) no playback equalization or ii) a second playback equalization different from the first playback equalization.

18. The apparatus of claim 17, wherein the processor and the memory are configured to detect using a trained machine-learning model.

19. The apparatus of claim 17, wherein the audio signal comprises different channels and the memory and the processor are configured to detect by analyzing the different channels, and wherein analyzing the different channels comprises comparing correlated content between two channels of the different channels.

20. The apparatus of claim 17, wherein the processor and the memory are configured to detect by analyzing the center channel of the audio signal.

21. The apparatus of claim 17, wherein the processor and the memory are configured to automatically apply to the audio signal the first playback equalization configured to enhance the speech within the content by transitioning to the first playback equalization from either i) no playback equalization or ii) the second playback equalization.

22. The apparatus of claim 17, wherein the second playback equalization comprises at least one of low frequency enhancement or music playback enhancement.

23. The apparatus of claim 17, wherein at least one of the first playback equalization or the one or more predefined conditions are configurable by a user.

24. The apparatus of claim 17, wherein the processor and the memory are further configured to analyze sound in an environment in which the audio signal is to be played back to help determine whether to apply the first playback equalization to the audio signal.

25. A non-transitory computer readable medium storing instructions that when executed by a device for processing and producing audio signals cause the device to:
during playback of an audio signal, analyze content of the audio signal prior to the playback of the content to determine whether one or more predefined conditions are met to indicate that the content includes speech;
in response to determining the one or more predefined conditions are met, automatically apply to the audio signal a first playback equalization configured to enhance the speech within the content; and
in response to determining the one or more predefined conditions are not met, apply to the audio signal i) no playback equalization or ii) a second playback equalization different from the first playback equalization.
